(19) United States
(12) Patent Application Publication
(10) Pub. No.: US 2020/0402867 A1
(43) Pub. Date: Dec. 24, 2020

(54) Method For Manufacturing Led Display

(71) Applicant: V Technology Co., Ltd., Yokohama-shi (JP)

(72) Inventors: Yoshikatsu Yanagawa, Yokohama-shi (JP); Koichiro Fukaya, Yokohama-shi (JP); Naoya Okura, Yokohama-shi (JP)

(73) Assignee: V Technology Co., Ltd., Yokohama-shi (JP)

(21) Appl. No.: 16/931,772

(22) Filed: Jul. 17, 2020

Related U.S. Application Data
(63) Continuation of application No. PCT/JP2019/001419, filed on Jan. 18, 2019.

(30) Foreign Application Priority Data
Feb. 6, 2018 (JP) 2018-019500

(51) Int. Cl. H01L 21/66; H01L 25/16; H01L 23/00

(52) U.S. Cl. CPC H01L 22/22; H01L 25/167; H01L 24/83; H01L 2224/83005; H01L 2924/1033; H01L 2224/83862; H01L 2224/83859; H01L 2224/83885; H01L 2924/12041; H01L 2224/83874

(57) ABSTRACT

The present invention provides a method for manufacturing an LED display including a wiring board and LEDs arranged at a constant distance from the wiring board. The method includes: aligning an LED substrate 1 having LEDs 11 with a wiring board 2, and pressing and joining the LED substrate onto the wiring board. Each LED has a bonding surface. The wiring board includes bonding layers. The aligning step is performed so that the bonding surfaces are joined on the bonding layers in the pressing and joining step. The method further includes: temporarily bonding the LEDs onto the wiring board by curing the bonding layers through irradiation with ultraviolet light UV; peeling off the LEDs from the LED substrate through irradiation with laser light L; and permanently bonding the LEDs onto the wiring board by heating the bonding layers of the LEDs so as to further cure the bonding layers.

This application is a continuation application of PCT/JP2019/001419, filed on Jan. 18, 2019.

### TECHNICAL FIELD

The present invention relates to a method for manufacturing a light emitting diode (LED) display, and more particularly, relates to a method for manufacturing an LED display in which LEDs are mounted on a wiring board with elastic support members interposed therebetween so that the LEDs are arranged at a constant distance from the wiring board.

### BACKGROUND ART

Conventionally known examples of image display devices include an image display device having an LED array in which LEDs are arranged in a matrix (see Patent Document 1, for example). The process of manufacturing such an image display device includes: providing a sapphire substrate on which LEDs formed; and mounting the LEDs onto a wiring board by peeling off the LEDs from the sapphire substrate, for example. According to Patent Document 1, in the mounting step, the electrodes of the LEDs are conductively bonded onto the wiring board with bonding conductive members interposed therebetween. The bonding conductive members, which are a type of elastic support member, are made of an elastic and electrically conductive material so as to be deformed by pressure and provide electrical connection.

### SUMMARY OF THE INVENTION

However, such bonding conductive members are likely to vary in height when they are pressed. As such, in the LED display manufactured by bonding the LEDs onto the wiring board with the bonding conductive members interposed therebetween, the LEDs are less likely to be arranged at a constant distance from the wiring board. However, on the other hand, using such bonding conductive members, which deform when pressed, is desirable to achieve a good joining between each LED and the wiring board when they are pressed together.

The present invention has been made to solve the above problems and has an object to provide a method for manufacturing an LED display in which LEDs are mounted on a wiring board with elastic support members interposed therebetween so that the LEDs are arranged at a constant distance from the wiring board.

To achieve the above object, the present invention provides a method for manufacturing an LED display by joining an LED substrate including a light transmitting wafer and LEDs, each having LED electrodes, formed in a plurality of rows at predetermined intervals on a first surface of the wafer onto a wiring board including wiring board electrodes and a circuit layer having a circuit configured to drive the LEDs and laminated on a first surface of the wiring board, and then by irradiating the LED substrate with laser light from a second surface of the wafer and peeling off the LEDs from the LED substrate so as to mount the LEDs on the wiring board so that the LED electrodes are electrically conductively connected to the wiring board electrodes. The method includes: aligning the LED substrate with the wiring board, and pressing and joining the LED substrate onto the wiring board. Each LED has the LED electrodes and a bonding surface on an upper surface of the LED. The bonding surface is disposed in a predetermined region neighboring the LED electrodes. The wiring board further includes: a circuit layer having a circuit configured to drive the LEDs and laminated on a first surface of the wiring board; elastic support members disposed at predetermined positions on the circuit layer; stop layers disposed at positions corresponding to positions of the bonding surfaces and configured to restrict compression of the elastic support members when the LED substrate and the wiring board are pressed together; and bonding layers having photocurable and thermosetting properties and disposed on the stop layers. In the aligning step, the bonding surfaces of the LEDs are positioned on upper surfaces of the bonding layers in the wiring board in preparation for joining the LED substrate onto the wiring board. The method further includes: temporarily bonding the LEDs onto the wiring board by curing the bonding layers through ultraviolet light irradiation from a second surface of the wafer while continuing to press the LED substrate against the wiring board; peeling off the LEDs from the LED substrate after laser light irradiation from the second surface of the wafer; and permanently bonding the LEDs onto the wiring board by heating the bonding layers of the LEDs mounted on the wiring board so as to further cure the bonding layers.

According to the method for manufacturing an LED display of the present invention, the stop layers restrict the compression of the elastic support members when the LED substrate pressed and joined onto the wiring board. Thus, the LEDs are permanently bonded onto the wiring board with the LEDs arranged at a constant distance from the wiring board.

### BRIEF DESCRIPTION OF THE DRAWINGS

FIGS. 1A to 1F are diagrams illustrating a method for manufacturing an LED display according to the present invention.

FIG. 2 is a flowchart showing steps of the method for manufacturing an LED display according to the present invention.

FIG. 3 is a plan view of the LED substrate shown in FIGS. 1A to 1D.

FIG. 4 is an enlarged view of a portion of the LED substrate shown in FIG. 3.

FIGS. 5A to 5C are diagrams illustrating the structure of the LED substrate shown in

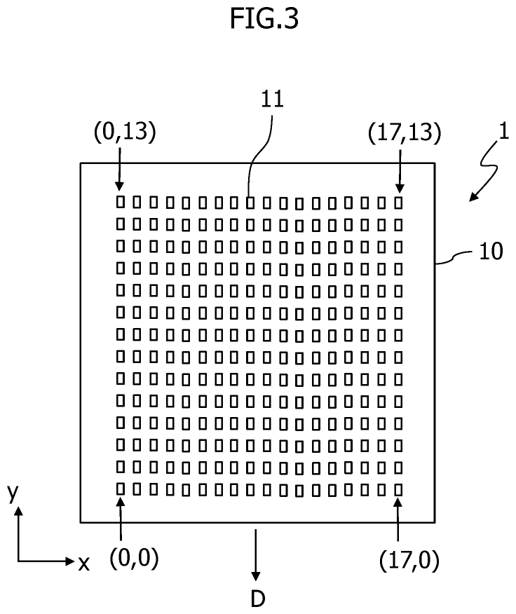

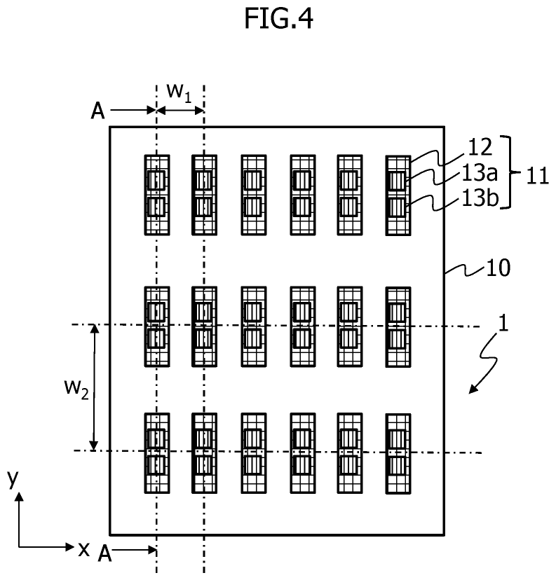

FIG. 3.

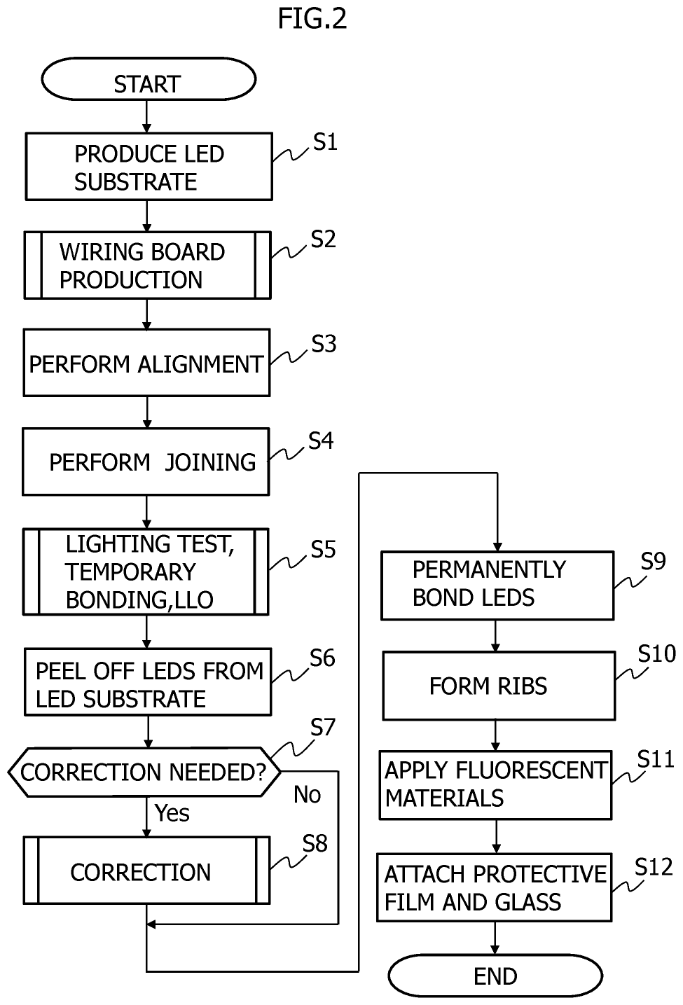

FIG. 6 is a flowchart showing details of the wiring board production step in FIG. 2.

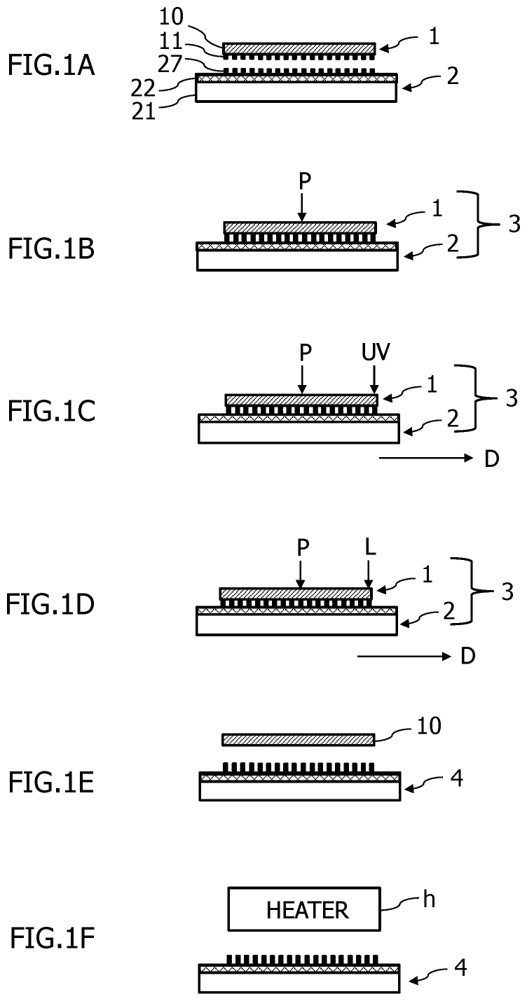

FIG. 7 is an enlarged plan view of a portion of the wiring board shown in FIGS. 1A to 1F.

FIGS. 8A to 8D are diagrams illustrating the structure of the wiring board shown in

FIG. 6.

FIG. 9 is a diagram illustrating how the LED substrate is aligned with the wiring board.

FIG. 10 is a diagram illustrating how the LED substrate is joined onto the wiring board.

FIG. 11 is a flowchart showing details of the lighting test, temporary bonding, and laser lift-off step in FIG. 2.

FIG. 12 is a flowchart showing details of the correction step in FIG. 2.

FIG. 13 is a plan view of an example of an LED substrate having an LED 11 to be determined to be defective.

FIG. 14 is a plan view of an example of an LED substrate for correction.

FIGS. 15A and 15B are diagrams illustrating the structure of the LED array board.

FIG. 16 is a plan view of an example of an LED display manufactured by the method for manufacturing an LED display according to the present invention.

FIG. 17 is a plan view of an LED substrate according to the modification.

FIGS. 18A to 18C are diagrams illustrating the structure of the LED substrate according to the modification.

FIG. 19 is a partial plan view of a wiring board according to the modification.

FIGS. 20A to 20C are diagrams illustrating the structure of the wiring board according to the modification.

FIGS. 21A and 21B are diagrams illustrating the structure of the LED array board according to the modification

### MODE FOR CARRYING OUT THE INVENTION

Hereinafter, an embodiment of the present invention will be described in detail with reference to the accompanying drawings.

FIGS. 1A to 1F are diagrams illustrating a method for manufacturing an LED display according to the present invention. FIG. 2 is a flowchart showing steps of the method for manufacturing an LED display according to the present invention. In the following description, it is assumed that each micro LED has external dimensions, for example, of 10 μm or less×30 μm or less. Furthermore, each of the micro LEDs in the LED display manufactured by the method has passed a lighting test, which will be described later, and thus is proved to have favorable light emission characteristics. Here, a major application of the method for manufacturing an LED display according to the present invention is manufacture of LED displays using micro LEDs. However, the method for manufacturing an LED display according to the present invention may also be applicable to manufacture of LED displays using LEDs having external dimensions greater than the above, depending on the intended application.

The method for manufacturing an LED display is characterized by including the steps shown in FIGS. 1A to 1F. Specifically, in this manufacturing method, first, a micro LED substrate 1 (simply referred to as “LED substrate 1” below) and a wiring board 2 are aligned with each other before they are joined together (see FIG. 1A). The LED substrate 1 includes a light transmitting wafer 10 and micro LEDs 11 (simply referred to as “LEDs 11” below). The LEDs 11 are formed in multiple rows at predetermined intervals on a first surface (upper surface) of the wafer 10. The wiring board 2 includes a support 21, a circuit layer 22, and structures 27. The circuit layer 22 has a circuit configured to drive the LEDs 11 and laminated on a first surface of the support 21. The structures 27 are provided on the circuit layer 22.

In the method for manufacturing an LED display, the LED substrate 1 is then pressed and joined onto the wiring board 2 with a pressure P (see FIG. 1B). In this manufacturing method, the LEDs 11 are then temporarily bonded onto the wiring board 2 by irradiation with ultraviolet light UV from a second surface (back surface) of the wafer 10 while the LED substrate 1 is pressed against the wiring board 2 with the pressure P (see FIG. 1C). In this manufacturing method, the wafer 10 is detached by laser lift-off (LLO) through irradiation with laser light L from the back surface of the wafer 10 (see FIG. 1D). Thereafter, the LED substrate 1 is released from the pressure P, and then the LEDs 11 are peeled off from the LED substrate 1 (see FIG. 1E), so that the LEDs 11 are mounted on the wiring board 2. Then, the LEDs 11 are heated by a heater h and thereby permanently bonded onto the wiring board 2 (see FIG. 1F). As a result, the LED electrodes of the LEDs 11 are electrically conductively connected to the wiring board electrodes of the wiring board 2.

This manufacturing method may further include a step of performing a lighting test on the LEDs subsequent to the step of pressing and joining the LED substrate 1 onto the wiring board 2 with the pressure P. Note that the arrow P in FIGS. 1B to 1D indicates that the LED substrate 1 is being pressed with the pressure P. As used herein for convenience of explanation, “test object 3” refers to the assembly of the LED substrate 1 and the wiring board 2 that are pressed together (see FIGS. 1B to 1D), and “LED array board 4” refers to the body in which the specified number of LEDs 11 are mounted on the wiring board 2 (see FIGS. 1E and 1F).

Specifically, as shown in FIG. 2, the method for manufacturing an LED display includes: producing an LED substrate (step S1); producing a wiring board (step S2); aligning the LED substrate with the wiring board (step S3); pressing and joining the LED substrate onto the wiring board (step S4); performing a lighting test, temporary bonding, and laser lift-off of the LEDs (step S5); peeling off the LEDs from the LED substrate (step S6); correcting any defective portion (steps S7 and S8); permanently bonding the LEDs (step S9); forming ribs (step S10); applying fluorescent materials (step S11); and attaching protective film and glass (step S12). Hereinafter, the steps of the method for manufacturing an LED display will be further described in this order.

In the LED substrate production step (step S1), the LEDs 11 are formed in multiple rows at predetermined intervals on the wafer 10 by, for example, a metal organic chemical vapor deposition (MOCVD) method, which is a type of vapor-phase epitaxial method. The LEDs 11 are formed using gallium nitride (GaN) as a main ingredient.

Each LED 11 may be an LED configured to emit near-ultraviolet light having a wavelength of, for example, 200 nm to 380 nm, or an LED configured to emit blue light having a wavelength of, for example, 380 nm to 500 nm. In other words, each LED 11 is a micro LED configured to emit light in a blue wavelength band or a near-ultraviolet wavelength band, for example. In view of light emission from miniaturized LEDs, when an LED display is manufactured using micro LEDs, it is preferable to use micro LEDs each configured to emit light in either of the above wavelength bands. This provides the resultant LED display with favorable light emission profiles.

FIG. 3 is a plan view of the LED substrate 1 shown in FIGS. 1A to 1D. In this embodiment, for convenience of explanation, it is assumed that the LEDs 11 are arranged on the wafer 10 at, for example, positions represented by the xy coordinates (0, 0) to (17, 13) in FIG. 3. In this embodiment, the LED substrate 1 may be conveyed in the direction of the arrow D (y direction).

FIG. 4 is an enlarged view of a portion of the LED substrate 1 shown in FIG. 3. Specifically, for ease of understanding, FIG. 4 shows a portion, containing LEDs 11 arranged in a matrix with three rows and six columns, of the LED substrate 1 of FIG. 3. The wafer 10, which is used as a substrate to be detached by laser lift-off, may be a sapphire substrate, for example.

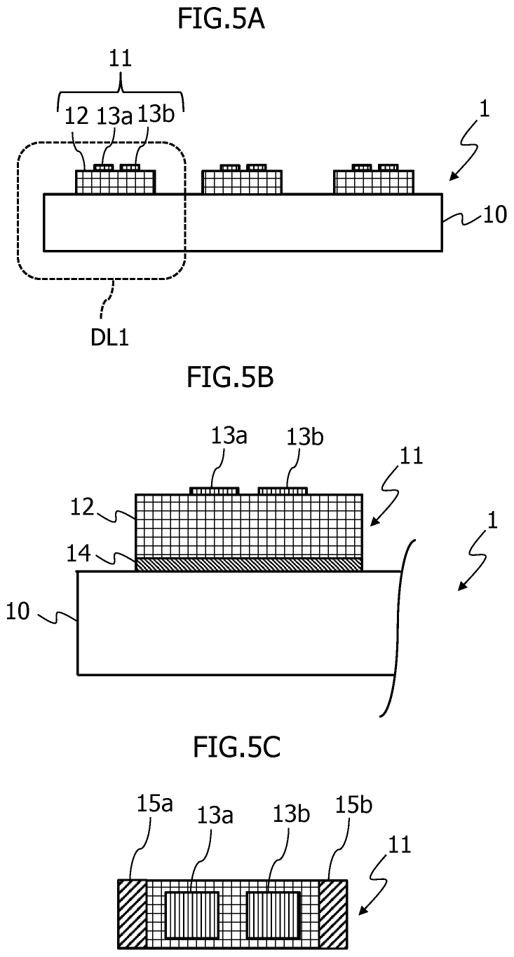

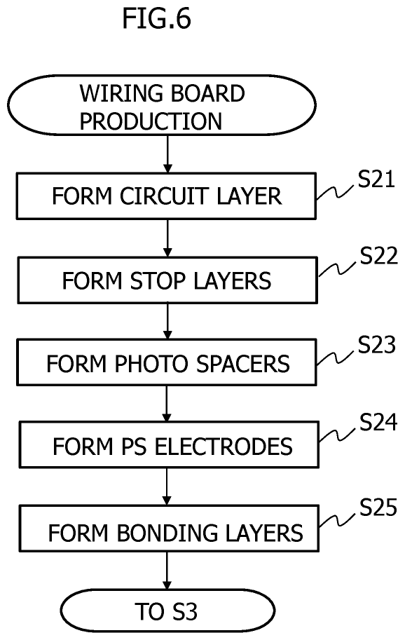

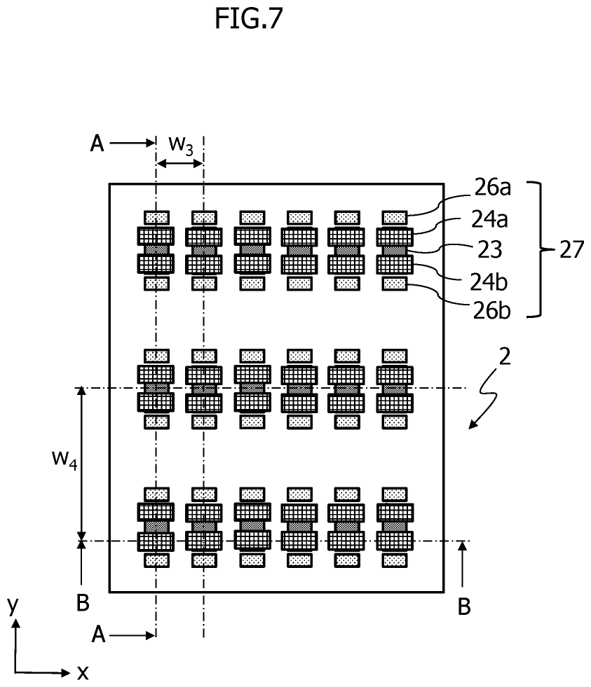

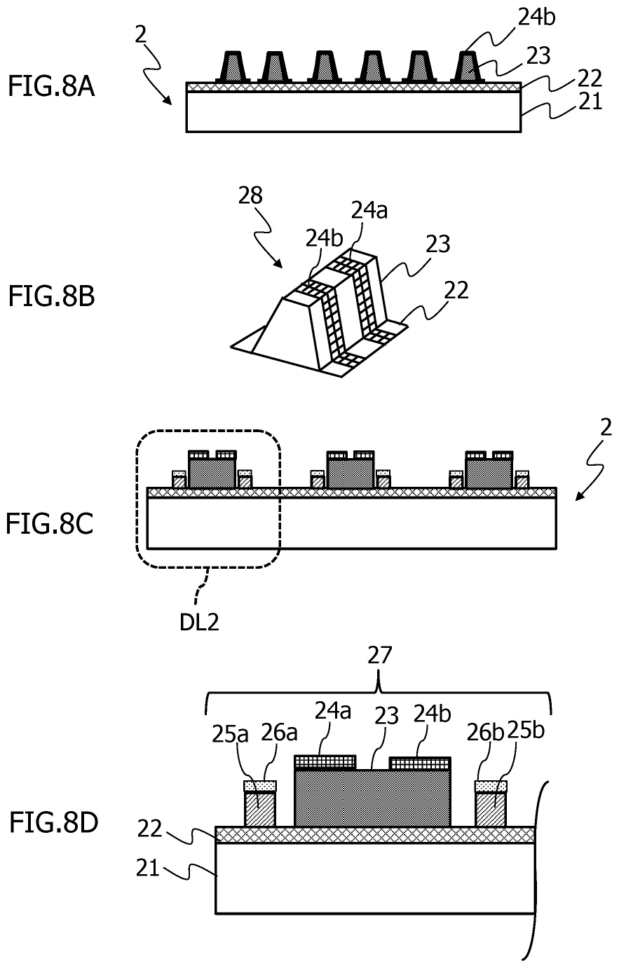

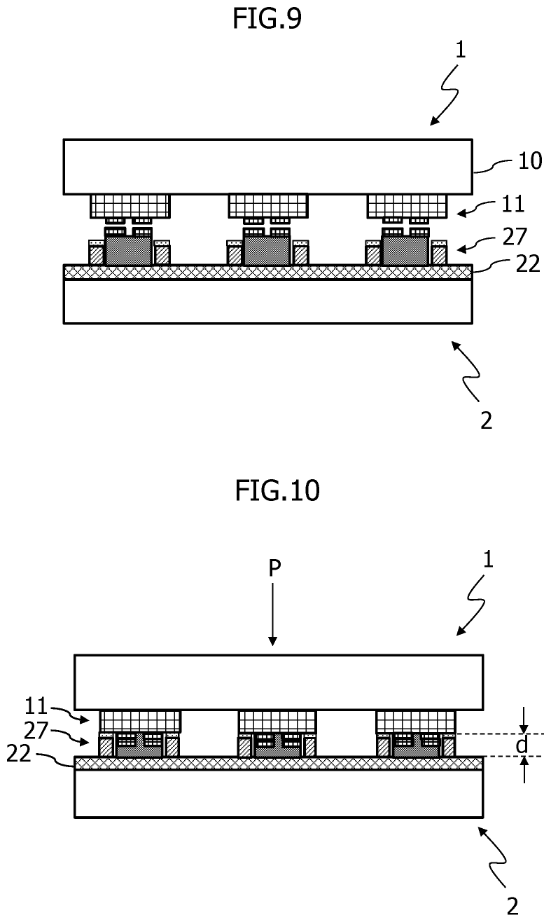

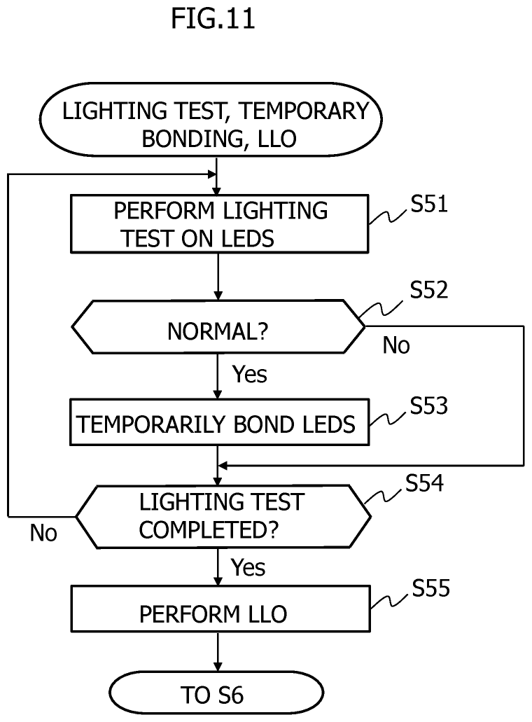

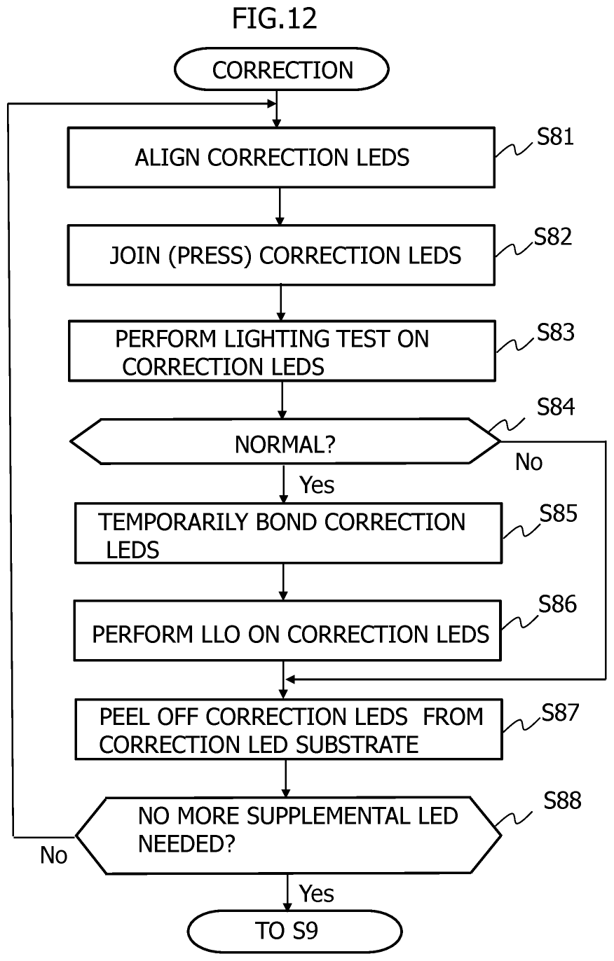

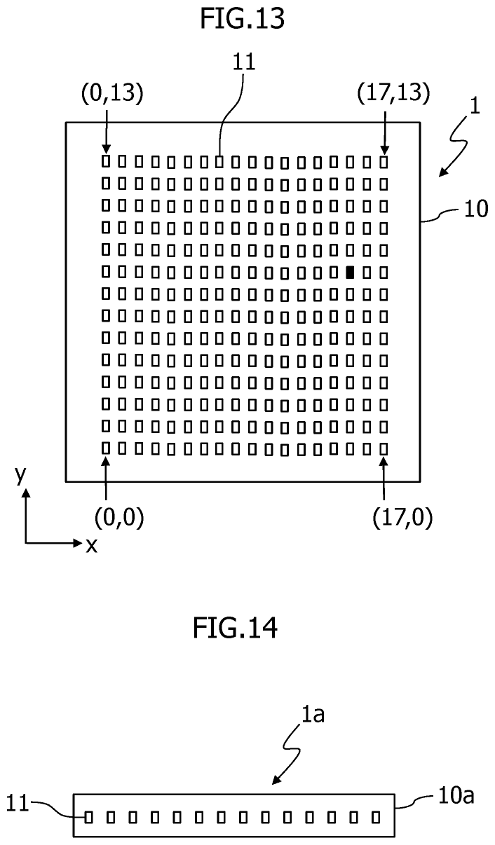

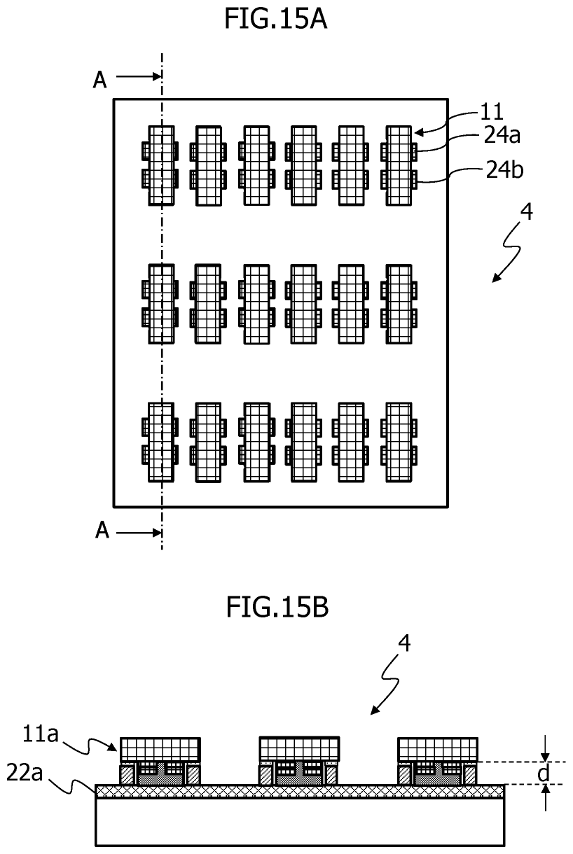

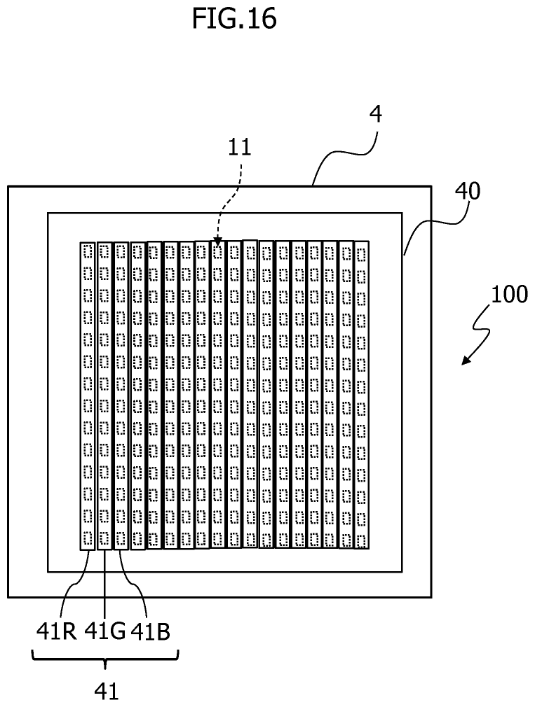

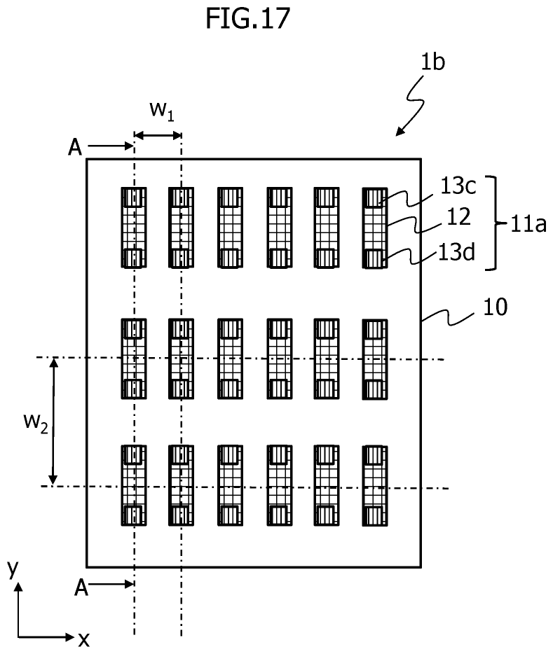

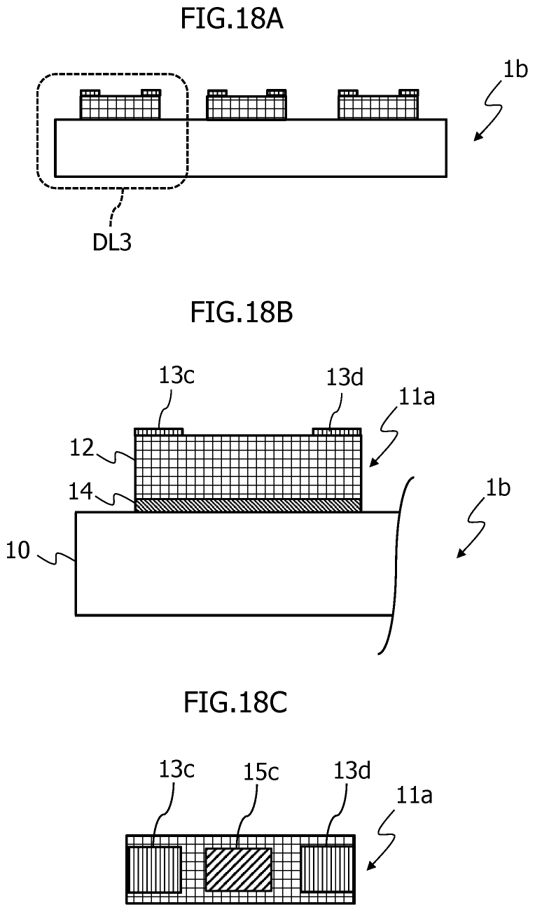

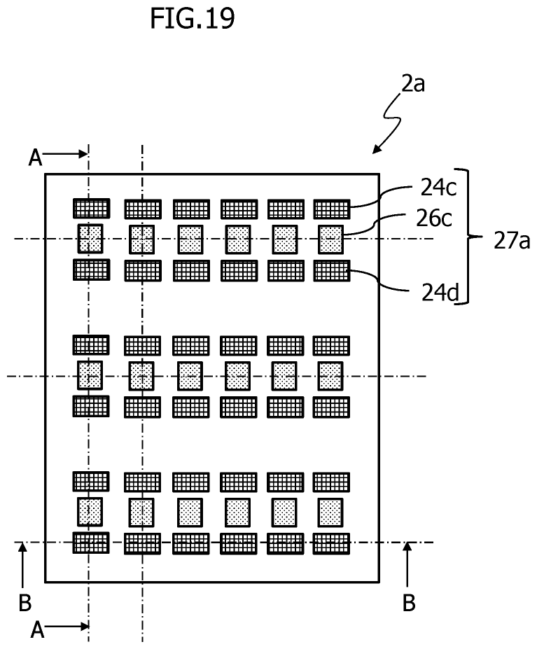

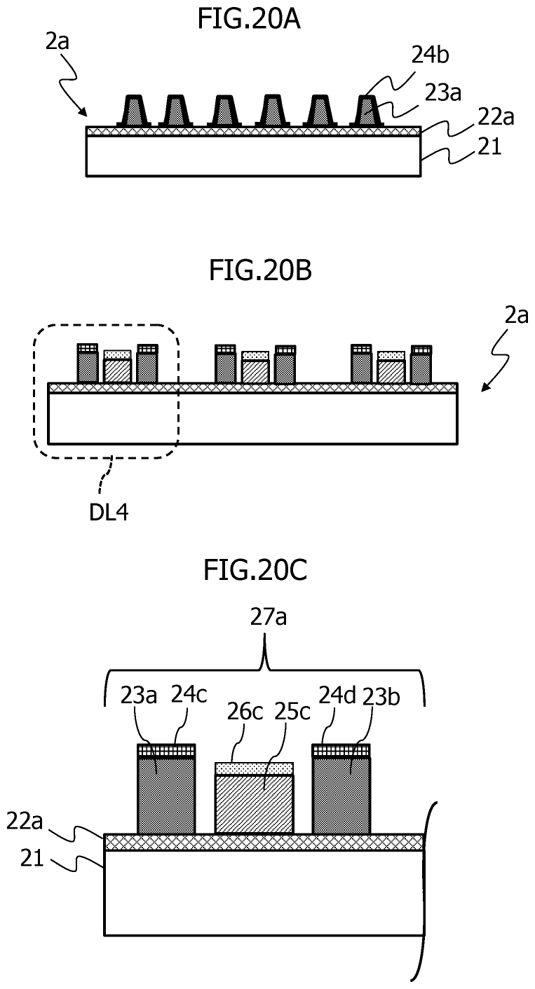

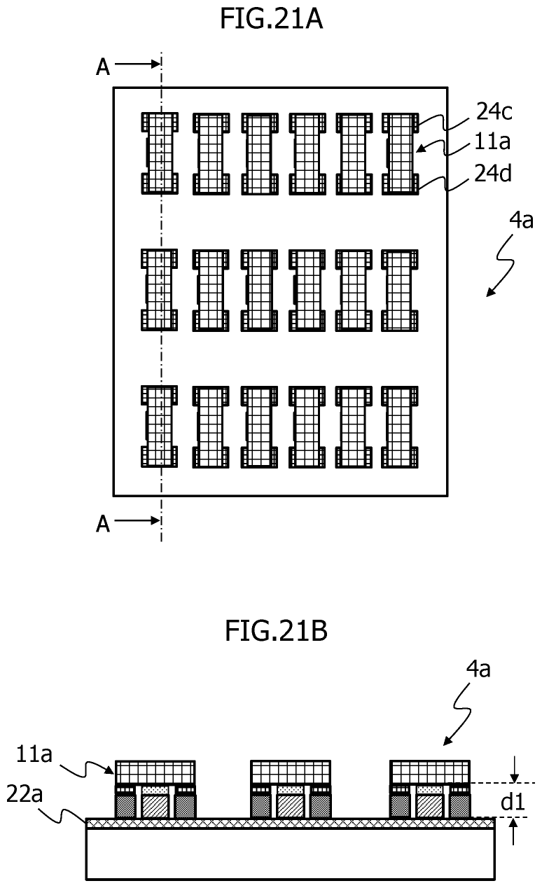

In the example shown in FIG. 4, the LEDs 11, each of which includes a compound semiconductor body 12 and LED electrodes 13a, 13b for energizing the LED 11, are arranged in a matrix with columns (extending in they direction) spaced at intervals of w₁ and rows (extending in the x direction) spaced at intervals of w₂. The intervals of w₁, w₂ are an example of “predetermined interval”. Note that, in the interest of simplicity, bonding surfaces 15a, 15b are not shown in FIG. 4. The bonding surfaces 15a, 15b are shown in FIG. 5C and will be described later.

FIGS. 5A to 5C are diagrams illustrating the structure of the LED substrate 1 shown in FIG. 4. FIG. 5A is a cross-sectional view taken along line A-A of FIG. 4. FIG. 5B is an enlarged view of a portion, enclosed by dashed line DL1 of FIG. 5A, of the LED substrate 1. FIG. 5C is a plan view showing the LED 11 on the portion, shown in FIG. 5B, of the LED substrate 1. Each LED 11 has the compound semiconductor body 12 including layers such as a release layer to be removed by laser lift-off and a light-emitting layer. As shown in FIG. 5B, the compound semiconductor body 12 includes a release layer 14 as its lowermost layer, and provided with the LED electrodes 13a, 13b on the upper surface of the uppermost layer of the compound semiconductor body 12. As used herein, the “upper surface” of each LED 11 refers to the upper surface of the uppermost layer of the compound semiconductor body 12 and corresponds to a surface, not adjacent to the wafer of the LED. In the following description, the “upper surface” of each LED 11 consistently indicates the surface, provided with the LED electrodes 13a, 13b, of the LED 11.

As shown in FIG. 5C, each LED 11 is characterized by having the rectangular bonding surfaces 15a, 15b in predetermined regions neighboring the LED electrodes 13a, 13b on the upper surface of the uppermost layer of the compound semiconductor body 12. In this embodiment, the predetermined regions neighboring the LED electrodes 13a, 13b in the LED 11 refer, for example, to regions selected to serve as bonding surfaces from the entire area, excluding the surface areas of the LED electrodes 13a, 13b, of the upper surface of the uppermost layer of the LED 11. More specifically, these neighboring regions of the LED 11 are designed so that the bonding surfaces 15a, 15b are suitably bonded onto the upper surfaces (exposed surfaces) of their corresponding bonding layers 26a, 26b of the wiring board 2 (see FIG. 7). In this embodiment, the LED substrate 1 and the wiring board 2 are configured so that the bonding surface 15a is bonded onto the upper surface of the bonding layer 26a and the bonding surface 15b is bonded onto the upper surface of the bonding layer 26b, for example.

Next, the wiring board production step (step S2) will be described.

FIG. 6 is a flowchart showing details of the wiring board production step in FIG. 2. As shown in FIG. 6, the wiring board production step (step S2) includes: forming a circuit layer (step S21); forming stop layers (step S22); forming photo spacers (PS) (step S23); and forming PS electrodes (step S24); and forming bonding layers (step S25). As described below, the wiring board 2 is produced by performing these five steps S21 to S25. Before describing these sub-steps of the wiring board production step in more detail, an illustrative structure of the wiring board 2 will first be described below.

FIG. 7 is an enlarged plan view of a portion of the wiring board 2 shown in FIGS. 1A to 1F. Specifically, FIG. 7 shows a portion, corresponding to the portion shown in FIG. 4 of the LED substrate 1, of the wiring board 2. FIGS. 8A to 8D are diagrams illustrating the structure of the wiring board 2. FIG. 8A is a cross-sectional view taken along line B-B of FIG. 7. FIG. 8B shows an electrode-laminated photo spacer. FIG. 8C is a cross-sectional view taken along line A-A of FIG. 7. FIG. 8D is an enlarged view of a portion, enclosed by dashed line DL2 of FIG. 8C, of the wiring board 2.

The wiring board 2 shown in FIG. 7 is configured to drive the LEDs 11. As shown in FIGS. 8A and 8D, the wiring board 2 includes the support 21 having a light transmitting property, the circuit layer 22 laminated on the support 21, and the structures 27 disposed at predetermined positions corresponding to those of the LEDs 11 of the LED substrate 1 shown in FIG. 4. Each structure 27, which is configured to be bonded onto the corresponding LED 11, includes a photo spacer 23, PS electrodes 24a, 24b, stop layers 25a, 25b, and the bonding layers 26a, 26b. Note that FIG. 7 does not include the reference numerals “25a” or “25b” since the stop layers 25a, 25b are hidden behind the bonding layers 26a, 26b in FIG. 7. The PS electrodes 24a, 24b are an example of “wiring board electrode”, and the photo spacer 23 is an example of “elastic support member”. In this embodiment, the elastic support member may be electrically insulative or conductive, depending on the intended application.

The structures 27 are arranged in a matrix with three rows and six columns in the example shown in FIG. 7. Specifically, the structures 27 are arranged in a matrix with columns spaced at intervals of w₃ and rows spaced at intervals of w₄. Here, in this embodiment, to facilitate aligning the LED board 1 with the wiring board 2, the intervals w₁ and w₂ are set equal to w₃ and w₄, respectively.

The support 21 is preferably a transparent glass or a film made of polyimide or the like. When the manufacturing method according this embodiment is used to manufacture a flexible LED display, a film made of polyimide or the like may be used. In the following description, the support 21 is assumed to be made of quartz glass, as an example.

Referring to the B-B cross-sectional view in FIG. 8A, each photo spacer 23 has, for example, a trapezoidal transverse cross section, and is configured to be pushed down and expand in the width direction of the trapezoidal cross section, when the LED substrate 1 and the wiring board 2 are pressed together. For convenience of explanation, the photo spacer 23 and the PS electrodes 24a, 24b laminated on the photo spacer 23 will be collectively referred to as an electrode-laminated photo spacer 28.

FIG. 8B is a perspective view of each of the electrode-laminated photo spacers 28. Each electrode-laminated photo spacer 28 is formed of an insulative photo spacer 23 stacked on the circuit layer 22 and the strip-shaped PS electrodes 24a, 24b laminated on the photo spacer 23 so as to be spaced away from each other. The distance between the PS electrodes 24a, 24b is set equal among the electrode-laminated photo spacers 28. In the plan view of the wiring board 2 in FIG. 7, the PS electrodes 24a, 24b are shown in rectangular shapes for illustrative purpose. It should be understood that actually, a portion, laminated on an uppermost portion of the photo spacer 23, of the PS electrode 24a is adapted to be bonded to the LED electrode 13a, and a portion, laminated on an uppermost portion of the photo spacer 23, of the PS electrode 24b is adapted to be bonded to the LED electrode 13b.

Referring to FIGS. 8C and 8D, the positional relationship of the components of the wiring board 2 as viewed from the front side of the structures 27 will be described. The wiring board 2 includes, for example: (1) the circuit layer 22 laminated on the support 21; (2) the photo spacers 23 disposed at predetermined positions on the circuit layer 22; (3) the PS electrodes 24a provided on the photo spacers 23 at the positions corresponding to the positions of the LED electrodes 13a; (4) the PS electrodes 24b provided on the photo spacers 23 at the positions corresponding to the positions of the LED electrodes 13b; (5) the stop layers 25a, 25b provided at positions neighboring each photo spacer 23; (6) the bonding layers 26a provided on the stop layers 25a; and (7) the bonding layers 26b provided on the stop layers 25b. The circuit layer 22 includes a circuit for driving the LEDs 11. The stop layers 25a, 25b are configured to restrict the compression of the photo spacers 23 when the LED substrate 1 and the wiring board 2 are pressed together. Each of the bonding layers 26a, 26b has photocurable and thermosetting properties.

Next, specific processing for producing the wiring board 2 (steps S21 to S25) will be described (see FIG. 6). In the step of forming a circuit layer (step S21), the circuit layer 22 is formed on the support 21 by forming LED on/off control patterns, a thin film transistor (TFT) circuit, and the like on the support 21 of the wiring board 2. Specifically, combined processes such as deposition, patterning, etching, and cleaning are performed to form the circuit layer 22 having the TFT circuit, the wiring for turning on and off the individual LEDs 11 to emit light and stop emitting light (LED on/off control patterns), and the like.

In the step of forming stop layers (step S22), the stop layers 25a, 25b are formed in a matrix on the circuit layer 22. The stop layers 25a, 25b are configured to control a gap formed between the LED substrate 1 and the wiring board 2 when they are pressed together. In other words, the stop layers 25a, 25b are pressure-resistant members with a function of maintaining a constant distance (gap) between the upper surface (the surface, facing the LED substrate 1) of the circuit layer 22 and the upper surface of each LED 11 when the LED substrate 1 and the wiring board 2 are pressed together.

Specifically, the stop layers 25a, 25b are made, for example, of a photosensitive photoresist material, which is typically used in a substrate in a liquid crystal display (LCD). The photosensitive photoresist material used in the stop layers 25a, 25b is a resist material which is pressure-resistant and harder than that used in the photo spacers 23.

In the step of forming stop layers (step S22), the photosensitive photoresist material is applied to the entire upper surface of the circuit layer 22, and it is then exposed and developed using a photomask. Thereby, the stop layers 25a, 25b are formed on the circuit layer 22 by patterning. All the stop layers 25a, 25b are formed to have the same thickness in the height direction.

The height of the stop layers 25a, 25b may be 5 μm, for example. The stop layers 25a, 25b are designed to have a height lower than that of the photo spacers 23 so that the stop layers 25a, 25b maintain a predetermined distance (gap) between the LED substrate 1 and the wiring board 2 when they are pressed and joined together and the photo spacers 23 are deformed.

Then, in the photo spacer forming step (step S23), an elastic, insulative resist material is deposited on the wiring board 2 so as to form the photo spacers 23 that bring the circuit terminals on the wiring board 2 into contact with the LED electrodes 13a, 13b. The height of the photo spacers 23 may be 8 μm, for example.

In the PS electrode forming step (step S24), metal patterns to serve as connectors to the LED electrodes 13a, 13b are formed on the photo spacers 23. Specifically, the metal patterns, to serve as the PS electrodes 24a, 24b, are formed by sputtering, vapor deposition, plating, or the like. Thus, a material with good electrical conductivity such as gold or aluminum is deposited on the photo spacers 23 and some portions of the circuit layer 22 so as to serve as the PS electrodes 24a, 24b (see FIG. 8B). In this way, the electrode-laminated photo spacers 28 are formed.

Then, in the bonding layer forming step (step S25), the bonding layers 26a are formed on the stop layers 25a of the wiring board 2 and the bonding layers 26b are formed on the stop layers 25b of the wiring board 2. Specifically, in the bonding layer forming step (step S25), an adhesive resist material with ultraviolet curable and thermosetting properties is deposited, exposed, and developed so as to be formed into the bonding layers 26a on the stop layers 25a and the bonding layers 26b on the stop layers 25b. Through the above steps S21 to S25, the wiring board 2 is produced. The adhesive material with ultraviolet curable and thermosetting properties is an example of a material for “bonding layer having photocurable and thermosetting properties”.

Next, the steps from the aligning step (step S3) to the permanent LED bonding step (step S9) will be described. In the aligning step (step S3), an aligning mechanism (not shown) is used to align the LED substrate 1 with the wiring board 2 (see FIG. 1A) so that the bonding surfaces 15a, 15b (as shown in FIG. 5C) are pressed and joined onto the upper surfaces of the bonding layers 26a, 26b (as shown in FIG. 8D) in the subsequent press joining step. Specifically, in the aligning step (step S3), the electrode portions (PS electrodes 24a, 24b) on the photo spacers 23 of the wiring board 2 are positioned on the electrode portions (LED electrodes 13a, 13b) of the LEDs 11 formed on the wafer 10 using alignment marks (not shown) provided on the LED substrate 1 and the wiring board 2, for example. As a result, the LED substrate 1 is aligned with the wiring board 2 so that, in the subsequent press joining step, the bonding surfaces 15a are pressed and joined onto the upper surfaces of the bonding layers 26a and the bonding surfaces 15b of the LED substrate 1 are pressed and joined onto the upper surfaces of the bonding layers 26b.

FIG. 9 is a diagram illustrating how the LED substrate is aligned with the wiring board. For clarity of illustration, FIG. 9 shows the LED substrate 1 of FIG. 5A and the wiring board 2 of FIG. 8C aligned with each other. In FIG. 9, the LED substrate 1 is aligned with the wiring board 2 so that the LEDs 11 formed on the upper surface of the wafer 10 of the LED substrate 1 face the structures 27 formed on the circuit layer 22 of the wiring board 2.

In the joining step (step S4), the LED substrate 1 is joined onto the wiring board 2. Specifically, according to this embodiment, after the LED substrate 1 is aligned with the wiring board 2 in the aligning step (step S3), the LED substrate 1 is pressed and joined onto the wiring board 2 (see FIG. 1B) so that, in the joining step (step S4), the LED electrodes 13a of the LEDs 11 come in contact with the PS electrodes 24a on the photo spacers 23 and the LED electrodes 13b of the LEDs 11 come in contact with the PS electrodes 24b on the photo spacers 23, for example.

FIG. 10 is a diagram illustrating how the LED substrate is joined onto the wiring board. After the LED substrate 1 is aligned with the wiring board 2 as shown in FIG. 9, the LED substrate 1 is lowered using a lifting mechanism (not shown), and thereby pressed and joined onto the wiring board 2 with the pressure P. FIG. 10 shows the LED substrate 1 and the wiring board 2 in such a state. Specifically, in the joining step (step S4), the LED electrodes 13a shown in FIG. 5B are pressed against the PS electrodes 24a shown in FIG. 8D, and the LED electrodes 13b shown in FIG. 5B are pressed against the PS electrodes 24b shown in FIG. 8D. As a result, each photo spacer 23 shown in FIG. 8D is elastically compressed like a cushion. However, the photo spacers 23 stop being compressed when the bonding layers 26a on the stop layers 25a come into contact with the bonding surfaces 15a of the LEDs 11 and the bonding layers 26b on the stop layers 25b come into contact with the bonding surfaces 15b of the LEDs 11. Thus, the amount of the compression of the photo spacers 23 while the LED substrate 1 is pressed against the wiring board 2 is restricted by the thickness of the stop layers 25a, 25b in the height direction. As described above, all the stop layers 25a, 25b have the same thickness in the height direction. As such, the distance (gap) between the upper surface of each LED 11 and the upper surface of the circuit layer 22 is maintained constant (at the distance d) (see FIG. 10).

That is, when the LED substrate 1 is strongly pressed against the wiring board 2, the photo spacers 23 are compressed and the bonding surfaces 15a, 15b of the LEDs 11 come in close contact with the bonding layers 26a and 26b on the wiring board 2. In this event, the gap formed between each LED 11 and the wiring board 2 is controlled by the thickness of the stop layers 25a, 25b in the height direction, and furthermore, the curvature and unevenness of the wafer 10 of the LED substrate 1 are reduced and the flatness of the wafer 10 is improved by such pressing.

Next, the lighting test, temporary bonding, and LLO step (step S5) will be described. The main purpose of this step is to remove defective LEDs 11 before permanently bonding the LEDs 11 onto the wiring board 2.

FIG. 11 is a flowchart showing details of the lighting test, temporary bonding, and laser lift-off step in FIG. 2. The lighting test, temporary bonding, and LLO step (step S5) includes performing a lighting test on the LEDs (steps S51, S52), temporary bonding the LEDs (step S53), determining whether the lighting test is completed (step S54), and performing laser lift-off of the LEDs (step S55).

In the LED lighting test step (step S51), which is performed after the LED substrate 1 and the wiring board 2 are pressed and joined together, the LEDs 11 are individually energized through the LED electrodes 13a, 13b of the LED substrate 1 and the PS electrodes 24a, 24b of the wiring board 2 to determine whether the respective LEDs 11 are defective or non-defective. Specifically, the LED lighting test (step S51) may be performed by applying a voltage to the circuit in the wiring board 2, and measuring the resultant resistance of the circuit or capturing an image of the LEDs 11 with a camera to observe the resultant light emissions of the LEDs 11, for example. In the LED lighting test step (step S51), the test object 3 shown in FIG. 1B is placed on a stage (not shown) and conveyed so that a set of the LEDs 11 arranged in a row extending in the direction perpendicular to the conveying direction of the test object 3 is inspected in each round. Thus, according to the present invention, the lighting test may be easily performed the LEDs 11 before the LEDs 11 are permanently bonded to the wiring board 2.

In this embodiment, it is assumed that the conveying direction of the test object 3 is the same as the conveying direction D of the LED substrate 1 shown in FIG. 3. Hereinafter, the first row of the LEDs 11 refers to the row of the LEDs 11 located at the xy coordinates (0, 0) to (17, 0) so as to extend in the x (transverse) direction in FIG. 3. Similarly, the second row of the LEDs 11 refers to the row of the LEDs 11 located at (0, 1) to (17, 1), . . . , the 13th row of the LEDs 11 refers to the row of the LEDs 11 located at (0, 12) to (17, 12), and the 14th row of the LEDs 11 refers to the row of the LEDs 11 located at (0, 13) to (17, 13). It is also assumed that, in the lighting test, the LEDs 11 in each row are inspected as a group in the order from the first row to the 14th row.

In FIG. 11, when the result of the lighting test for the LEDs 11 in an inspection-target row is “normal” (Yes in step S52), the operation proceeds to step S53. When the result of the lighting test for the LEDs 11 in the inspection-target row is “abnormal” (No in step S52), the operation proceeds to step S54. As used herein, the test result “normal” indicates all the LEDs 11 in the inspection-target row have passed the lighting test and are determined to be non-defective LEDs with good light emission performance. On the other hand, the test result “abnormal” indicates at least one of the LEDs 11 in the inspection-target row has failed the lighting test and is determined to be defective.

When all the LEDs 11 in the inspection-target row are determined to be non-defective, these LEDs 11 are temporarily bonded onto the wiring board 2 (step S53) by curing the bonding layers 26a, 26b thereof by irradiation with ultraviolet light UV using an ultraviolet light irradiation means (not shown). Note that, in the temporary bonding step, the LEDs 11 determined to be non-defective are temporary fixed (subjected to a first-stage bonding) onto the wiring board 2 to the extent that the LEDs 11 will be transferred on the wiring board 2 after the laser lift-off of the wafer 10. A preferable example of the source of ultraviolet light UV suitable for this purpose is a laser diode (LD) or a light-emitting diode having a wavelength of 300 to 420 nm. In other words, in the temporary LED bonding step (step S53), a single row of the LEDs 11 that have been determined as “normal” in the last lighting test are irradiated with a linear beam of ultraviolet light UV from the back surface of the wafer 10 so that the bonding layers 26a, 26b of these the LEDs 11 are cured.

In the temporary LED bonding step (step S53), the area irradiated by ultraviolet light UV for curing the bonding layers 26a, 26b may be controlled so that the bonding layers 26a, 26b of a single LED 11 are cured or so that the bonding layers 26a, 26b of multiple LEDs 11 are cured. Thus, according to this embodiment, in which an adhesive material with ultraviolet curable and thermosetting properties is used in the bonding layers 26a, 26b, the temporary LED bonding step (step S53) may be locally performed by controlling irradiation with ultraviolet light UV. Thus, according to this embodiment, it is possible to perform selective temporary bonding so that the LEDs 11 determined to be non-defective are temporarily bonded, but the LEDs 11 determined to be defective are not temporarily bonded, for example.

In the test completion determining step (step S54), it is determined whether the lighting test has been completed for all the LEDs 11. When it is determined that the lighting test has not been completed (No in step S54), the operation returns to step S51 so as to inspect the next row of the LEDs 11. When it is determined that the lighting test has been completed for all the LEDs 11 (Yes in step S54), the operation proceeds to step S55.

In the laser lift-off step (step S55), the temporarily bonded LEDs 11 are separated from the LED substrate 1 by laser lift-off (LLO). To perform this laser lift-off step, the test target 3 is further conveyed to a laser lift-off device. The laser lift-off device used in the laser lift-off step (step S55) may have a configuration as disclosed in Japanese Patent Application No. 2017-007342 filed by the same applicant of the present application, for example. In the laser lift-off step (step S55), when the test object 3 is conveyed to the laser lift-off device, the LEDs 11 in the first row are positioned at laser irradiation positions, first. Then, only when the LEDs 11 in the first row have passed the lighting test in step S51, the LEDs 11 in the first row are separated from the LED substrate 1 by laser lift-off by irradiating the release layers 14 of these irradiation-target LEDs 11 with a linear beam of the laser light L focused thereon through mask patterns (see FIG. 1D). As an alternative, the laser lift-off device may be configured to irradiate a single LED 11 at a time with laser light L. However, in this embodiment, multiple LEDs 11 in a row are collectively irradiated with the laser light L at one time to perform the LLO more efficiently.

On the other hand, when the LEDs 11 in the first row have failed the lighting test in step S51, the LEDs 11 in the first row are not subjected to laser lift-off, and the LEDs 11 in the second row are then positioned at the laser irradiation positions. After that, the second to 14th rows the LEDs 11 are sequentially processed by repeating the same procedures. When all the LEDs 11 have been processed in step S55, the operation proceeds to the LED peeling off step (step S6) of FIG. 2.

A preferable example of the laser light source for laser lift-off is an ultraviolet picosecond laser (with a wavelength four times longer than that of a YAG laser and with a pulse width of 10 psec). Specifically, a laser with a wavelength of 263 nm or 266 nm and with a pulse width of a picosecond order is preferable, for example. Appropriate selection of the laser light source, such as listed above, prevents the laser irradiation from adversely affecting the LEDs 11.

As described above, in the laser lift-off step (step S55), the LEDs 11 that are not subjected to the temporary bonding (i.e., defective LEDs 11) are excluded from the irradiation targets of the laser light L so as to remain on the LED substrate 1. Thus, according to the present invention, the LEDs 11 determined to be non-defective are selectively subjected to the temporary bonding and laser lift-off, so that the non-defective LEDs 11 are selectively mounted on the wiring board 2 in the LED peeling off step (step S6).

In the LED peeling off step (step S6), the LEDs 11 having been separated from the LED substrate 1 of the test object 3 by laser lift-off are peeled off from the LED substrate 1. The laser lift-off step (step S55) and the LED peeling off step (step S6) collectively correspond to the step of peeling off the LEDs 11 from the LED substrate 1 after laser light irradiation from the back surface of the wafer 10.

Assume a case in which all the LEDs 11 are determined to be non-defective in the lighting test, temporary bonding, and LLO step (step S5), for example. In this case, all the LEDs 11 are peeled off from the LED substrate 1 and thereby finally mounted (transferred) on the wiring board 2 in step S6 (see FIG. 1E). In this case, after all the LEDs 11 are peeled off from the LED substrate 1 and thereby finally mounted on the wiring board 2, only the wafer 10 is left in the LED substrate 1. FIG. 1E, which includes the wafer 10 and the LED array board 4, shows such a state. Assume another case in which at least one of the LEDs 11 is determined to be defective in the lighting test, temporary bonding, and LLO step (step S5). In this case, the LEDs 11 in the row containing the defective LED 11 are removed with the LED substrate 1 and thus, not mounted on the wiring board 2 in step S6. Note that, in the lighting test, temporary bonding, and LLO step (step S5), the temporary LED bonding step (step S53) may be performed after all the first to 14th rows of the LEDs 11 are subjected to the lighting test.

Then, it is determined whether there is any defective portion to be corrected with supplemental LEDs. When it is determined that there is any defective portion to be corrected with supplemental LEDs (Yes in step S7), the operation proceeds to the correction step (step S8). When it is determined that there is no defective portion to be corrected with supplemental LEDs (No in step S7), the operation proceeds to the permanent LED bonding step (step S9).

FIG. 12 is a flowchart showing details of the correction step in FIG. 2. In the correction step (step S8), a vacancy due to the absence of the LEDs 11, including the at least one LED 11 determined to be defective, are filled with non-defective LEDs. FIG. 13 is a plan view of an example of an LED substrate having the LED 11 to be determined to be defective. Assume a case in which, as shown in FIG. 13, it is determined that the LED (indicated in black in FIG. 13) located at (15, 8) in the ninth row is defective, for example. In this case, the LEDs 11 in the ninth row are subjected to neither the temporary LED bonding step (step S53) nor the laser lift-off step (step S55), as described above. As a result, the LEDs 11 in the ninth row remain on the LED substrate 1, and the LEDs 11 in the rows other than the ninth row are mounted on the wiring board 2.

FIG. 14 is a plan view of an example of an LED substrate for correction (referred to as “correction LED substrate” below). The correction LED substrate 1a, which is pre-stocked, includes a single row of LEDs (referred to as “correction LEDs” below) 11. As shown in FIG. 14, the correction LED substrate 1a further includes a wafer 10a that has an elongated shape corresponding to a single row of LEDs 11.

In the LED aligning step for correction (step S81), the correction LED substrate 1a is aligned with a vacancy due to the absence of the ninth row of the LEDs 11 in preparation for pressing and joining the correction LED substrate 1a against the wiring board 2. Then, in the LED joining step for correction (step S82), the correction LED substrate 1a is lowered and pressed and joined onto the wiring board 2. Thereafter, in the same manner as in step S51 described above, the lighting test is performed on the correction LEDs (step S83).

Then, it is determined whether the correction LEDs are “normal” (step S84). When it is determined that the correction LEDs arranged in a row are non-defective (Yes in step S84), the correction LEDs are determined to be “normal” and the operation proceeds to the temporary bonding step for correction (step S85). When it is determined that at least one of the correction LEDs arranged in the row is defective (No in step S84), the correction LEDs are determined to be “abnormal” and the operation skips the temporary bonding step and the laser lift-off step for correction and proceeds to step S87. Then, in the peeling off step for correction (step S87), the LED substrate 1a for correction is released from the pressure and removed, and the operation proceeds to step S88.

When the operation proceeds from step S84 to the temporary bonding step for correction (step S85), the correction LED substrate 1a is irradiated with ultraviolet light UV to cure the bonding layers 26a, 26b in step S85. In the laser lift-off step for correction (step S86), the correction LED substrate 1a is detached from the correction LEDs by laser lift-off. Then, in the peeling off step for correction (step S87), the correction LEDs, which have been determined to be non-defective, are peeled off from the correction LED substrate 1a, so that the LEDs are supplementally mounted on the wiring board 2.

Then, it is determined whether no more defective portions remain to be corrected with supplemental LEDs 11 (step S88). When at least one LED 11 has been determined to be defective in step S84, a defective portion remains to be corrected with supplemental LEDs 11 in step S88 (No in step S88), and the operation returns to step S81 so that a new correction LED substrate 1a is aligned with the defective portion. When the correction LEDs have been determined to be “normal” in step S84, and thus, steps S84 to S86 have been performed, there is no defective portion remains to be corrected with supplemental LEDs 11 in step S88 (Yes in step S88), and the operation proceeds to step S9 of FIG. 2.

The processing in the correction step (step S8) described above may be summarized as follows. First, the wiring board 2 on which non-defective LEDs are mounted and which has a vacancy due to the absence of a row of the LEDs 11 containing the LED 11 determined to be defective (such a wiring board 2 will be referred to as “wiring board 2 that lacks a row of LEDs 11”) is aligned with the correction LED substrate (replacement LED substrate) 1a that includes a single row of correction LEDs (replacement LEDs) (step S81). Specifically, in step S81, the bonding surfaces of the correction LEDs arranged in a row are aligned with the upper surfaces of the bonding layers in the portion, on which the LEDs 11 are not mounted, of the wiring board 2 that lacks a row of LEDs 11. Then, in the LED joining step for correction (step S82), the correction LED substrate 1a is pressed onto the wiring board 2 that lacks a row of LEDs 11. Then, the lighting test is performed on the correction LEDs (step S83), and only when determined to be non-defective, the correction LEDs are temporarily bonded onto the wiring board 2 in the temporary bonding step for correction (step S85). Then, in the laser lift-off step for correction (step S86), the correction LED substrate 1a is detached from the correction LEDs by laser lift-off. Subsequently, in the peeling off step for correction (step S87), the correction LEDs, which have been determined to be non-defective, are peeled off from the correction LED substrate 1a, so that the correction LEDs 11 are supplementally mounted on the wiring board 2 that lacks a row of LEDs 11. Thereby, defective LEDs 11 are prevented from being mounted on the wiring board 2 in the correction step (step S8).

Then, in the permanent LED bonding step (step S9), the LED array board 4 having the LEDs 11 temporarily bonded on the wiring board 2 is heated by an external heater h to further cure the bonding layers 26a, 26b by thermosetting and thus, permanently bond the LEDs 11 onto the wiring board 2 (see FIG. 1F). In this way, the LED array board 4 including the non-defective LEDs 11 is produced.

FIGS. 15A and 15B are diagrams illustrating the structure of the LED array board. FIG. 15A is a plan view of the LED array board 4, obtained by transferring the LEDs 11 from the LED substrate 1 of FIG. 4 and thereby mounting the LEDs 11 onto the wiring board 2 of FIG. 7. FIG. 15B is a cross-sectional view taken along line A-A of FIG. 15A. In the LED array board 4, the distance (gap) d between the upper surface of each LED 11 and the upper of the circuit layer 22 is constant. Thus, this embodiment allows accurate gap control and provides the LED array board 4 with an improved flatness. Furthermore, this embodiment allows increasing the bonding areas, thereby increasing bonding strength.

In the step of forming ribs (step S10), ribs (light-shielding partitions) for defining cells to be filled with fluorescent materials for the respective LEDs 11 are formed.

In the subsequent step of applying fluorescent materials (step S11), R, G, and B fluorescent materials are injected (applied) between the ribs. Steps S10, S11 may be performed by using a technique as disclosed in Japanese Patent Application No. 2017-232743 filed by the same applicant of the present application, for example.

In the subsequent step of attaching protective film and glass (step S12), a protective film and a protective glass are attached to the resultant structure. Through the steps described above, an LED display is manufactured.

FIG. 16 is a schematic plan view of an LED display. An LED display 100 shown in FIG. 16 is configured to display color images, and includes the LED array board 4, a fluorescence emission layer array 40, a protective film (not shown), and a protective glass (not shown).

The fluorescence emission layer array 40 is provided on the LEDs 11. The fluorescence emission layer array 40 includes red, green and blue fluorescence emission layers 41. The fluorescence emission layers 41 are provided on (the display surface of) the LED array board 4 and separated from each other by the partitions (ribs), not shown, in FIG. 16. Each of the red, green and blue fluorescence emission layers 41 is configured to be excited by excitation light emitted from the underlying LEDs 11, thereby converting the excitation light into fluorescence of the specified color by wavelength conversion.

Specifically, corresponding to the three primary colors of red, green and blue, the fluorescence emission layers 41 include red fluorescence emission layers 41R, green fluorescence emission layers 41G, and blue fluorescence emission layers 41B, which are arranged side by side on the LEDs 11. Each of the red, green and blue fluorescence emission layers 41R, 41G, 41B is made of a fluorescent resist containing a fluorescent colorant (pigment or die) of the specified color. FIG. 16 shows an example in which the red, green and blue fluorescence emission layers 41R, 41G, 41B, each of which has a belt shape, are arranged in a stripe pattern. Alternatively, however, the red, green and blue fluorescence emission layers 41R, 41G, 41B may be provided corresponding to the individual LEDs 11.

As described above, according to the present invention, it is possible to provide an LED display that includes the LEDs 11 arranged at a constant distance from the wiring board 2 and thus has favorable light emission profiles. Furthermore, according to the present invention, it is possible to perform a lighting test on the LEDs 11 without removing the LEDs 11 from the wafer 10, as necessary, during the manufacturing process of the LED display. This allows only non-defective LEDs 11 to be temporarily bonded, separated by laser lift-off, and thereby mounted on the wiring board 2 while preventing defective LEDs 11 from being mounted on the wiring board 2. Thus, according to the present invention, it is possible to improve the manufacturing efficiency of the LED display.

Next, a modification of the above embodiment will be described. The modification differs from the above embodiment in the structures of the LED substrate 1 and the wiring board 2, but is the same in other respects. Accordingly, the flowcharts used in the above description may also be applied to the modification. The same components as those described above will be indicated by the same reference numerals, and description thereof will be omitted if unnecessary. Thus, in the following description, among other features, differences from the above embodiment will be discussed in detail.

FIG. 17 is a plan view of an LED substrate according to the modification. As in FIG. 4, FIG. 17 shows a portion, containing micro LEDs 11a (simply referred to as “LEDs 11a” below) arranged in a matrix with three rows and six columns, of a LED substrate 1b, as an example. The LED substrate 1b includes a wafer 10 and multiple LEDs 11a arranged in a matrix on the wafer 10.

The LEDs 11a, each of which includes a compound semiconductor body 12 and LED electrodes 13c, 13d, are arranged in a matrix with columns (extending in they direction) spaced at intervals of w₁ and rows (extending in the x direction) spaced at intervals of w₂.

FIGS. 18A to 18C are diagrams illustrating the structure of the LED substrate 1b according to the modification. FIG. 18A is a cross-sectional view taken along line A-A of FIG. 17. FIG. 18B is an enlarged view of a portion, enclosed by dashed line DL3 of FIG. 18A, of the LED substrate 1b. FIG. 18C is a plan view showing the LEDs 11a on the portion, shown in FIG. 18B, of the LED substrate 1b. The LEDs 11a have the same configuration as the LEDs 11 except that the positions of the electrodes and the positions of the bonding surfaces differ from those of the LEDs 11. In the LEDs 11a, LED electrodes 13c, 13d are provided at both ends on the upper surface of the uppermost layer of each compound semiconductor body 12. The LED electrodes 13c, 13d are an example of “LED electrode”.

As shown in FIG. 18C, each LED 11a is characterized by having a single bonding surface 15c in a predetermined region neighboring the LED electrodes 13c, 13d on the upper surface of the uppermost layer of the compound semiconductor body 12. In the modification, the predetermined region neighboring the LED electrodes 13c, 13d in the LED 11a refers, for example, to a region selected to serve as bonding surfaces from the entire area, excluding the surface areas of the LED electrodes 13c, 13d, of the upper surface of the uppermost layer of the LED 11a. In other words, the predetermined region according to the modification is designed so that the bonding surfaces 15c of the LEDs 11a are suitably bonded onto the upper surfaces of their corresponding bonding layers 26c of a wiring board 2a (see FIG. 19). The wiring board 2a and bonding layers 26c will be described later. In the modification, the bonding surface 15c is provided at the center of the upper surface of the uppermost layer of each compound semiconductor body 12.

FIG. 19 is a partial plan view of a wiring board according to the modification. Specifically, FIG. 19 shows a portion, corresponding to the portion shown in FIG. 17 of the LED substrate 1b, of the wiring board. FIGS. 20A to 20C are diagrams illustrating the structure of the wiring board according to the modification. FIG. 20A is a cross-sectional view taken along line B-B of FIG. 19. FIG. 20B is a cross-sectional view taken along line A-A of FIG. 19. FIG. 20C is an enlarged view of a portion, enclosed by dashed line DL4 of FIG. 20B, of the wiring board 2a.

The wiring board 2a shown in FIG. 19 is configured to drive the LEDs 11a. As shown in FIG. 20C, the wiring board 2 includes the support 21, a circuit layer 22a laminated on the support 21, and the structures 27a disposed at predetermined positions corresponding to those of the LEDs 11a of the LED substrate 1b shown in FIG. 17. Each structure 27a includes photo spacers 23a, 23b, PS electrodes 24c, 24d, a stop layer 25c, and a bonding layer 26c.

More specifically, in the wiring board 2a, the photo spacers 23a, 23b and the stop layers 25c are provided on the circuit layer 22a having a circuit configured to drive the LEDs 11a. The PS electrodes 24c are laminated on the photo spacers 23a and the PS electrodes 24d are laminated on the photo spacers 23b. The stop layers 25c, provided at predetermined positions corresponding to the positions of the bonding surfaces 15c of the LEDs 11a, are configured to restrict the compression of the photo spacers 23a, 23b when the LED substrate 1a and the wiring board 2a are pressed together. The bonding layers 26c having photocurable and thermosetting properties are provided on the stop layers 25c. The PS electrodes 24c, 24d are an example of “wiring board electrode”, and each photo spacer 23a, 23b is an example of “elastic support member”. The photo spacers 23a, 23b may be electrically conductive.

In this modification, a portion, laminated on an uppermost portion of the photo spacer 23a, of the PS electrode 24c is adapted to be bonded to the LED electrode 13c, and a portion, laminated on an uppermost portion of the photo spacer 23b, of the PS electrode 24d is adapted to be bonded to the LED electrode 13d.

When the photo spacers 23a, 23b are electrically conductive, the PS electrodes 24c, 24d are not necessarily formed on the photo spacers 23a, 23b, and the photo spacers 23a, 23b may serve as wiring board electrodes, instead. For example, the LED substrate 1a and the wiring board 2a may be configured so that the LED electrodes 13c of the LEDs 11a are directly connected to the photo spacers 23a and the LED electrodes 13d of the LEDs 11a are directly connected to the photo spacers 23d. As yet another alternative, the photo spacers 23a, 23b may be electrically insulative depending on the intended application.

FIGS. 21A and 21B are diagrams illustrating the structure of the LED array board 4a. FIG. 21A is a plan view of the LED array board 4a, obtained by transferring the LEDs 11a from the LED substrate 1b of FIG. 17 and thereby mounting the LEDs 11a onto the wiring board 2a of FIG. 19. FIG. 21B is a cross-sectional view taken along line A-A of FIG. 21A. As in the LED array board 4 described above, the distance (gap) dl between the upper surface of each LED 11a and the upper surface of the circuit layer 22a is constant in the LED array board 4a. Thus, this modification allows accurate gap control and provides the LED array board 4a with an improved flatness. Furthermore, this modification allows increasing the bonding areas, thereby increasing bonding strength. As will be understood, the LED array board 4a according to this modification may be used to produce an LED display.

Note that the order of the steps in the method for manufacturing an LED display according to the present invention are not limited to that described in the above embodiment. For example, the LED substrate production step (step S1) and the wiring board production step (step S2) may be performed in the reverse order to the above. Furthermore, in the method for manufacturing an LED display according to the present invention, the LED substrate 1 and the wiring board 2 may be prepared in advance, and the processing of the flowchart of FIG. 2 may start from the aligning step (step S3).

### REFERENCE SYMBOL LIST

1, 1b LED substrate
1a correction LED substrate
2, 2a wiring board
4, 4a LED array board
10 wafer
11, 11a LED
12 compound semiconductor body
13a, 13b, 13c, 13d LED electrode
15a, 15b, 15c bonding surface
21 support
22, 22a circuit layer
23, 23a, 23b photo spacer (elastic support member)
24a, 24b, 24c, 24d PS electrode (wiring board electrode)
25a, 25b, 25c stop layer
26a, 26b, 26c bonding layer
100 LED display

1. A method for manufacturing an LED display by joining an LED substrate onto a wiring board, the LED substrate including a light transmitting wafer and LEDs formed in a plurality of rows at predetermined intervals on a first surface of the wafer, each LED having LED electrodes, the wiring board including wiring board electrodes and a circuit layer having a circuit configured to drive the LEDs and laminated on a first surface of the wiring board, and then by irradiating the LED substrate with laser light from a second surface of the wafer and peeling off the LEDs from the LED substrate so as to mount the LEDs on the wiring board so that the LED electrodes are electrically conductively connected to the wiring board electrodes, the method comprising:
aligning the LED substrate with the wiring board,
wherein each LED having the LED electrodes and a bonding surface on an upper surface of the LED, the bonding surface being disposed in a predetermined region neighboring the LED electrodes,
wherein the wiring board further includes:
a circuit layer having a circuit configured to drive the LEDs and laminated on a first surface of the wiring board;
elastic support members disposed at predetermined positions on the circuit layer;
stop layers disposed at positions corresponding to positions of the bonding surfaces and configured to restrict compression of the elastic support members when the LED substrate and the wiring board are pressed together; and
bonding layers having photocurable and thermosetting properties and disposed on the stop layers, and
wherein, in the aligning step, the bonding surfaces of the LEDs are positioned on upper surfaces of the bonding layers in the wiring board in preparation for joining the LED substrate onto the wiring board;
pressing and joining the LED substrate onto the wiring board;
temporarily bonding the LEDs onto the wiring board by curing the bonding layers through ultraviolet light irradiation from a second surface of the wafer while continuing to press the LED substrate against the wiring board;
peeling off the LEDs from the LED substrate after laser light irradiation from the second surface of the wafer; and
permanently bonding the LEDs onto the wiring board by heating the bonding layers of the LEDs mounted on the wiring board so as to further cure the bonding layers.

2. The method for manufacturing an LED display, according to claim 1, the method further comprising, subsequent to the pressing and joining step:
inspecting the LEDs in the LED substrate,
wherein, in the inspecting step, the LEDs are individually energized through the LED electrodes and the wiring board electrodes to determine whether the respective LEDs are defective or non-defective.

3. The method for manufacturing an LED display, according to claim 2,
wherein, when the LEDs are determined to be non-defective in the inspecting step,
in the temporarily bonding step, the LEDs determined to be non-defective are temporary bonded onto the wiring board, and
in the peeling off step, the LEDs determined to be non-defective are peeled off from the LED substrate and mounted on the wiring board.

4. The method for manufacturing an LED display, according to claim 2,
wherein, when at least one of the LEDs is determined to be defective in the inspecting step,
in the temporarily bonding step, one or more LEDs at least including the at least one LED determined to be defective are not temporary bonded onto the wiring board, and
in the peeling off step, the one or more LEDs that are not temporary bonded are not subjected to the laser light irradiation and remain on the LED substrate.

5. The method for manufacturing an LED display, according to claim 4,
wherein the one or more LEDs that are not temporary bonded onto the wiring board in the temporarily bonding step are LEDs in a row including the at least one LED determined to be defective, and
wherein, in the peeling off step, the LEDs in the row are not subjected to the laser light irradiation so that LEDs in the other rows are selectively peeled off from the LED substrate and mounted on the wiring board.

6. The method for manufacturing an LED display, according to claim 5, further comprising:
aligning a replacement LED substrate including a single row of replacement LEDs with the wiring board on which non-defective LEDs are mounted and which has a vacancy due to an absence of the row of the LEDs including the at least one LED determined to be defective,
wherein, in the aligning step, the bonding surfaces of the replacement LEDs in the single row are positioned on upper surfaces of bonding layers located in the vacancy of the wiring board; and
pressing and joining the replacement LED substrate onto the wiring board,
wherein, when the replacement LEDs are determined to be non-defective in the inspecting step,
in the temporarily bonding step, the replacement LEDs determined to be non-defective are temporary bonded onto the wiring board having the vacancy, and
in the peeling off step, the replacement LEDs determined to be non-defective are peeled off from the replacement LED substrate and supplementally mounted on the wiring board so as to fill the vacancy.

7. The method for manufacturing an LED display, according to claim 1,
wherein the LEDs are micro LEDs each configured to emit light in a blue wavelength band or a near-ultraviolet wavelength band.
